(19) United States
(12) Patent Application Publication
(10) Pub. No.: US 2024/0288643 A1
(43) Pub. Date: Aug. 29, 2024

(54) THERMAL MANAGEMENT IN AN OPTICAL SUB-ASSEMBLY

(71) Applicant: LUMENTUM TECHNOLOGY UK LIMITED, NORTHAMPTONSHIRE (GB)

(72) Inventors: Andrew STRANGE, Devon (GB); Colin SMITH, Paignton (GB)

(21) Appl. No.: 18/298,828

(22) Filed: Apr. 11, 2023

Related U.S. Application Data
(60) Provisional application No. 63/487,439, filed on Feb. 28, 2023.

(51) Int. Cl. G02B 6/42

(52) U.S. Cl. CPC G02B 6/4271; G02B 6/4238; G02B 6/4257

(57) ABSTRACT

An optical sub-assembly includes a housing; at least one component integrated within the housing, wherein the at least one component is configured to generate heat during operation; and a heat spreader integrated as part of the housing or integrated within the housing. The heat spreader is thermally coupled to the at least one component to receive heat from the at least one component. The heat spreader contains a phase change material that is configured to undergo phase transitions between a first phase state and a second phase state. The heat spreader is configured to utilize the phase transitions to spread heat throughout the heat spreader. The heat spreader is configured to equalize a heat load or minimize a temperature gradient of the optical sub-assembly.

### CROSS-REFERENCE TO RELATED APPLICATION

This Patent application claims priority to U.S. Patent Application No. 63/487,439, filed on Feb. 28, 2023, and entitled “THERMAL MANAGEMENT IN AN OPTICAL SUB-ASSEMBLY.” The disclosure of the prior Application is considered part of and is incorporated by reference into this Patent Application.

### TECHNICAL FIELD

The present disclosure relates generally to optical sub-assemblies and to thermal management of optical sub-assemblies.

### BACKGROUND

An optical module may have at least one of an optical transmission function or an optical receive function. In general, in order to implement the optical transmission function and the optical receive function, the optical module includes one or a plurality of optical sub-assemblies (OSAs).

An OSA may be configured to convert an electrical signal into an optical signal, or vice versa. For example, an OSA may be used for optical communications in which electrical signals are used to transmit or receive information in a digital format or an analog format. An OSA configured as a transmitter may be configured to convert an electrical signal into an optical signal and transmit the optical signal over an optical fiber connected to the OSA. An OSA configured as a receiver may be configured to receive an optical signal (e.g., the optical signal transmitted by the transmitter OSA) and convert the optical signal back into an electrical signal for signal processing (e.g., demodulation or decoding). An OSA configured as a transceiver that includes both a transmitter and a receiver may be configured to transmit and receive optical signals.

### SUMMARY

In some implementations, an optical sub-assembly includes a housing that defines an enclosure, wherein the housing comprises sidewalls and a base that extends between the sidewalls, and wherein one of the sidewalls comprises an optical port configured to at least one of receive a receive optical signal or transmit a transmit optical signal; at least one component integrated within the enclosure, wherein the at least one component is configured to generate heat during operation; and a heat spreader that extends at least partially between the sidewalls, wherein the heat spreader is integrated in the base or integrated within the enclosure, wherein the heat spreader is thermally coupled to the at least one component to receive heat from the at least one component, wherein the heat spreader contains a phase change material that is configured to undergo phase transitions between a first phase state and a second phase state, and wherein the heat spreader is configured to utilize the phase transitions to spread heat throughout the heat spreader, wherein the heat spreader is configured to equalize a heat load or minimize a temperature gradient of the optical sub-assembly.

In some implementations, an optical sub-assembly includes a housing; at least one component integrated within the housing, wherein the at least one component is configured to generate heat during operation; and a heat spreader integrated as part of the housing or integrated within the housing, wherein the heat spreader is thermally coupled to the at least one component to receive heat from the at least one component, wherein the heat spreader contains a phase change material that is configured to undergo phase transitions between a first phase state and a second phase state, and wherein the heat spreader is configured to utilize the phase transitions to spread heat throughout the heat spreader, wherein the heat spreader is configured to equalize a heat load or minimize a temperature gradient of the optical sub-assembly.

### BRIEF DESCRIPTION OF THE DRAWINGS

FIG. 1A is a cross-section diagram of an OSA according to one or more implementations.

FIG. 1B is a plan view of the OSA shown in FIG. 1A according to one or more implementations.

FIG. 2A is a surface plot of a temperature flow simulation for an OSA that does not include an integrated heat spreader.

FIG. 2B is a surface plot of a temperature flow simulation for an OSA that includes an integrated heat spreader according to one or more implementations.

FIG. 3A is a cross-section diagram of an OSA according to one or more implementations.

FIG. 3B is a cross-section diagram of an OSA according to one or more implementations.

### DETAILED DESCRIPTION

The following detailed description of example implementations refers to the accompanying drawings. The same reference numbers in different drawings may identify the same or similar elements.

An OSA may include one or more components that produce heat during operation. For example, an OSA may include at least one laser source, at least one thermoelectric cooler (TEC), at least one digital signal processor (DSP), at least one light modulator driver, at least one transimpedance amplifier (TIA), at least one photodiode, and/or other integrated circuit (IC) components. Some of the components may be high-power components, which, during operation, can create a significant temperature difference across the OSA. In other words, operation of some of the components of the OSA may create an unequal heat distribution within the OSA, resulting in an unequal temperature gradient across the OSA. For example, hot spots within the OSA may be formed, which can elevate a heat load (e.g., thermal load) on components of the OSA located at or near the hot spots. Elevated temperatures can reduce a performance of a component, reduce a reliability of a component, and/or cause premature failure of a component. In some cases, operation of the one or more high-power components can create a significant temperature difference across a surface (e.g., an exterior surface) of the OSA, and/or drive up a temperature of the one or more high-power components, which can thereby limit an operation of the high-power components and/or limit an operation of one or more components proximate to the high-power components.

Including an external heat management system to control heat produced by the one or more high-power components is limited by available space on an exterior of the OSA and a thermal efficiency of such an external heat management system. For example, not every system can accommodate an external heat management system. Moreover, an ability of an external heat management system to spread heat substantially evenly across the OSA may be limited. Thus, an external heat management system may not be capable of equalizing at least one of a heat load or a temperature gradient of the OSA.

Some implementations described herein provide an OSA that includes a heat spreader that is integrated as part of a housing of the OSA or that is integrated within the housing. The OSA may include at least one optical component, such as a laser source, a tunable laser, a pump laser, or a photodiode. The heat spreader may be thermally coupled to at least one heat-generating component of the OSA to receive the heat from the at least one heat-generating component. A heat-generating component may be a laser source, a TEC, a DSP, a light modulator driver, a TIA, a photodiode, and/or other IC components. A heat-generating component may be or may include an active component. An active component, in contrast to a passive component, may be a device that is configured to inject power or energy into a circuit, and may have an ability to amplify a signal or produce a power gain.

The heat spreader may contain a phase change material that is configured to undergo phase transitions between a first phase state (e.g., a gaseous phase) and a second phase state (e.g., a liquid phase), and the heat spreader may be configured to utilize the phase transitions to spread the heat throughout the heat spreader. In some implementations, the heat spreader may be configured to utilize the phase transitions to spread the heat evenly or substantially evenly throughout the heat spreader. The heat spreader may be configured to equalize a heat load or to minimize a temperature gradient of the OSA by spreading the heat throughout the heat spreader.

In some implementations, the heat spreader may include one or more thermally conductive components (e.g., one or more heat spreading components), such as one or more chambers (e.g., evaporation/condensation chambers, vapor chambers, and/or other thermally conductive chambers), one or more heat pipes, and/or other thermally conductive components. The heat spreader may be integrated into the OSA (e.g., to form a single and/or monolithic component). For example, the heat spreader may be part of a structure (e.g., a base, a package wall, a lid, a cover, or another structural component) of the OSA (as opposed to being a separate, external component that is associated with the OSA). In some implementations, the heat spreader may be incorporated within the housing (e.g., within an enclosure formed by the housing) and may be coupled to part of the housing.

Accordingly, the heat spreader may directly contact, or may be in close proximity to, one or more heat sources of the OSA (e.g., one or more heat-generating components). As a result, temperature differences across the OSA may be reduced and a temperature gradient across the OSA may be equalized, which may reduce a likelihood of a drive-up of temperature of one or more components of the OSA. Equalizing the temperature gradient across the OSA may improve a thermal management of the OSA, as compared to using an external heat management system.

The heat spreader may be configured to conduct heat away from high-power dissipation areas of the OSA, such as areas associated with a TIA, a DSP, a laser source, and/or a light modulator driver, to lower or no power dissipation areas of the OSA. This may be effective to equalize (or spread) a heat load and temperature gradient in the OSA (e.g., within a package or housing of the OSA). The heat spreader may be included within any region of the OSA (e.g., a package of the OSA) and may use convection and/or condensation (e.g., phase transitions) to redistribute heat. In some implementations, two or more heat spreaders may be integrated within the OSA to redistribute heat and to minimize the temperature gradient of the OSA. For example, a first heat spreader may be included in a first part or a first region of the OSA, such as in the base, and a second heat spreader may be included in a second part or a second region of the OSA, such as the lid.

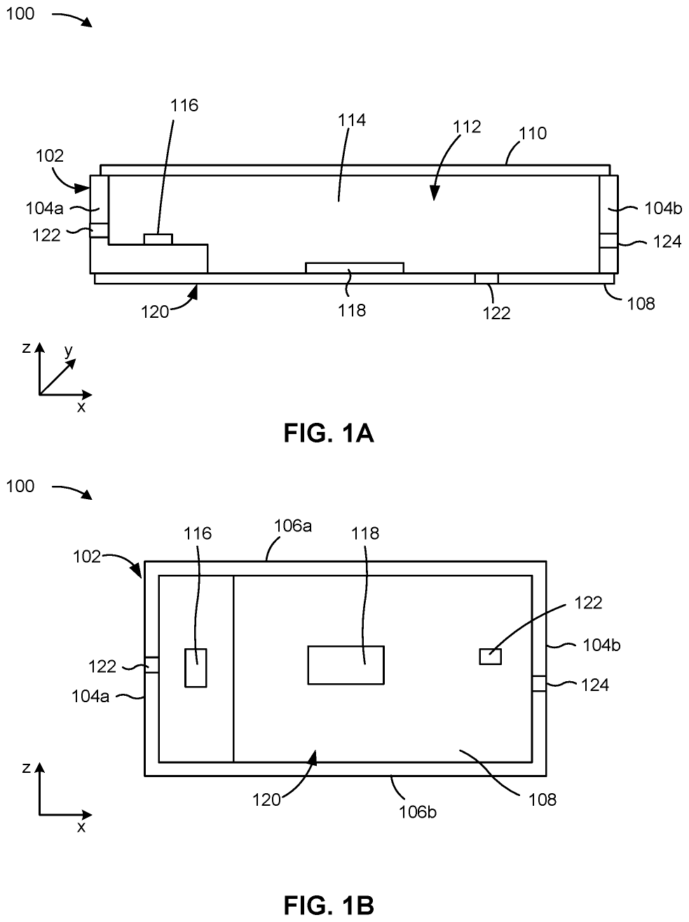

FIG. 1A is a cross-section diagram of an OSA 100 according to one or more implementations. FIG. 1B is a plan view of the OSA 100 shown in FIG. 1A according to one or more implementations. The OSA 100 may be a receiver OSA, a transmitter OSA, or a transceiver OSA. The OSA 100 includes a housing 102 that may include sidewalls 104a, 104b, 106a, and 106b, a base 108 (e.g., bottom package base) that extends between the sidewalls 104a and 104b in a first planar direction (e.g., an x-direction) and extends between the sidewalls 106a and 106b in a second planar direction (e.g., a y-direction), and a lid 110 (e.g., a top package cover) that is arranged opposite to the base 108 and that extends between the sidewalls 104a and 104b in the first planar direction (e.g., the x-direction) and extends between the sidewalls 106a and 106b in the second planar direction (e.g., the y-direction). The housing 102 may be made of polymer, ceramic, metal, and/or a metal alloy. For example, the housing 102 may be made of a polymer, a ceramic material, Kovar®, copper tungsten (CuW), or any combination of a polymer, ceramic, Kovar, and/or copper tungsten (CuW). In some implementations, other metals and metal alloys can be used for the housing 102, such as copper molybdenum (CuMo) and/or copper (Cu). In some implementations, the housing 102 may be made of multi-metal layers of ceramic in combination with multi-metal layers or of a polymer in combination with multi-metal layers. The housing 102, together with the sidewalls 104a, 104b, 106a, and 106b, the base 108, and the lid 110, may define an enclosure 112 in which one or more components of the OSA 100 are arranged. In addition, a package assembly 114 may be arranged in the enclosure 112. The package assembly 114 may include one or more components of the OSA integrated therein. The package assembly 114 may comprise a polymer, a ceramic, a metal, a metal alloy, or a combination thereof that encapsulates the one or more components of the OSA. Thus, the package assembly 114 may occupy at least part of the enclosure 112 or may occupy the entire enclosure 112.

The OSA 100 includes one or more heat-generating components 116 and 118 that are integrated within the enclosure 112 and may be encased by the package assembly 114. For example, the heat-generating component 118 may be arranged directly on the base 108, and the heat-generating component 116 may be arranged on another structure that is separated from the base 108. The one or more heat-generating components 116 and 118 may be configured to generate heat during operation. Accordingly, the heat-generating components 116 and 118 are heat sources that are integrated within the OSA 100. In some implementations, the heat-generating component 116 may be a laser source (e.g., a laser, a tunable laser, or a pump laser), a TEC, a DSP, a light modulator driver that drives the laser source, a TIA, a photodiode, an IC, or an IC component, including one or more active components. The heat-generating component 118 may be a laser source (e.g., a laser, a tunable laser, or a pump laser), a TEC, a DSP, a light modulator driver that drives the laser source, a TIA, a photodiode, an IC, or an IC component, including one or more active components.

The OSA 100 further includes an integrated heat spreader 120 that extends at least partially between the sidewalls 104a, 104b, 106a, and 106b. The integrated heat spreader 120 may be integrated in the base 108 (e.g., the heat spreader is part of the base 108) or may be integrated within (e.g., arranged within) the enclosure 112. In this example, the integrated heat spreader 120 is integrated in the base 108 and may extend from the sidewall 104a to the sidewall 104b and/or from the sidewall 106a to the sidewall 106b. In some implementations, the integrated heat spreader 120 is used as the base 108. Thus, the integrated heat spreader 120 may form the base 108. Since the base 108 is mechanically coupled to the sidewalls 104a, 104b, 106a, and 106b, the integrated heat spreader 120 may also be mechanically coupled to the sidewalls 104a, 104b, 106a, and 106b. The base 108 may be mechanically coupled to the package assembly 114, for example, by soldering or brazing. For example, the base 108 may be soldered or brazed to a ceramic, a metal, and/or a metal alloy of the package assembly 114. Thus, in some implementations, the integrated heat spreader 120 may be mechanically coupled to the package assembly 114, for example, by soldering or brazing, particularly in implementations in which the integrated heat spreader 120 is used as the base 108. In some implementations, the base 108 may be mechanically coupled to fewer than all of the sidewalls 104a, 104b, 106a, and 106b (e.g., to only one sidewall, to only two sidewalls, or to only three sidewalls).

The integrated heat spreader 120 may be thermally coupled to the heat-generating components 116 and 118 to receive at least part of the heat generated by the heat-generating components 116 and 118. In addition, the integrated heat spreader 120 is a phase change-based heat spreader that uses a phase change material to transfer and spread heat. Accordingly, the integrated heat spreader 120 includes a chamber (e.g., a vapor chamber or a vacuum chamber) that contains the phase change material that is configured to undergo phase transitions between a first phase state (e.g., a gaseous state or an evaporated state) and a second phase state (e.g., a liquid state). The integrated heat spreader 120 may be configured to utilize the phase transitions to spread the heat throughout the integrated heat spreader 120. For example, the phase change material may evaporate from a liquid to a vapor when the phase change material comes in contact with a hot interface of the integrated heat spreader 120. Having absorbed heat from the hot interface, the vapor may travel within the chamber to a cooler region of the chamber, where the vapor condenses back into a liquid and releases latent heat into a cooler region of the OSA 100. Thus, the phase change material may be used to efficiently transfer heat from one area of the OSA 100 (e.g., a high-power dissipation area or a hot spot) to another area of the OSA 100 (e.g., a low-power dissipation area or a cool spot) in order to minimize a temperature gradient of the OSA 100.

The chamber of the integrated heat spreader 120, which utilizes convection and/or condensation of the phase change material to redistribute the heat throughout the integrated heat spreader 120, can be located in any region of the housing 102 or in any region within the enclosure 112. For example, the chamber of the integrated heat spreader 120 may extend substantially throughout the base 108 (e.g., in at least one of the x-direction or the y-direction) in order to redistribute the heat equally or substantially equally throughout the OSA 100. Thus, the integrated heat spreader 120 may spread (e.g., redistribute) the heat equally or substantially equally within the enclosure 112.

As a result, the integrated heat spreader 120 may be configured to equalize a heat load or minimize a temperature gradient of the OSA 100. For example, the integrated heat spreader 120 may be configured to equalize a heat load or minimize a temperature gradient of the OSA 100 by reducing temperatures in hotter regions of the OSA 100 and increasing temperatures in cooler regions of the OSA 100 such that temperature differences between different regions of the OSA 100 are reduced. In some implementations, the integrated heat spreader 120 may be configured to minimize the temperature gradient of the OSA 100 such that temperatures of the OSA 100 are maintained within 10% of a mean temperature of temperatures present throughout the OSA 100. In some implementations, the integrated heat spreader 120 may be configured to minimize the temperature gradient of the OSA 100 such that temperatures of the OSA 100 have a substantially lower temperature distribution from the mean temperature of the OSA 100. In some implementations, the integrated heat spreader 120 may prevent or reduce a likelihood of a drive-up of a temperature of the one or more high-power components, for example, to prevent or reduce a likelihood of a thermal runaway of the one or more high-power components that may cause degradation in performance of a component or that may cause component failure.

In some implementations, the integrated heat spreader 120 may be arranged within the enclosure 112. For example, the integrated heat spreader 120 may be arranged inside the enclosure 112 and may be mechanically coupled to (e.g., directly coupled to) the base 108. In some implementations, the integrated heat spreader 120 may be integrated in the lid 110 or used as the lid 110 instead of being integrated in the base 108. In some implementations, the integrated heat spreader 120 may be integrated in the base 108 and another heat spreader, having a chamber and a phase change material, may be integrated in the lid or within the enclosure 112. Additionally, or alternatively, the integrated heat spreader 120 or another heat spreader, having a chamber and a phase change material, may be integrated in one or more sidewalls 104a, 104b, 106a, and 106b. In some implementations, the integrated heat spreader 120 may be configured to spread the heat evenly or substantially evenly in the first planar direction between the sidewalls 104a and 104b of the OSA 100 and spread the heat evenly or substantially evenly in the second planar direction between the sidewalls 106a and 106b.

In some implementations, the OSA 100 may include an electrical feedthrough 122 that is arranged at the base 108 or at a sidewall 104a, 104b, 106a, or 106b. The electrical feedthrough 122 may be configured to at least one of receive an electrical receive signal from an outside of the housing 102 and provide the electrical receive signal to one or more components within the enclosure 112 or transmit an electrical transmit signal from one or more components within the enclosure 112 to the outside of the housing 102. For example, the electrical feedthrough 122 may be used to receive power signals used for supplying power to more components within the enclosure 112 (e.g., to one or more of the heat-generating components 116 and 118). In some implementations, the electrical feedthrough 122 may be a high-speed feedthrough for transmitting or receiving high-speed data.

In some implementations, the OSA 100 may include one or more optical ports 124 (e.g., optical feedthroughs) which may be arranged in the base 108, one or more the sidewalls 104a, 104b, 106a, 106b, and/or the lid 110. The one or more optical ports 124 may be configured to allow optical signals to pass through the housing 102. For example, the optical signals may include a receive optical signal from an external source (e.g., from an optical transmitter) and/or a transmit optical signal. Thus, the OSA 100 may include circuitry and optical components associated with receiving and/or transmitting optical signals. In some implementations, the optical signals may be optical communication signals and the one or more optical ports 124 may be coupled to an optical fiber used for transmitting the optical communication signals.

In some implementations, the housing 102 may be a hermetically sealed housing. Thus, the enclosure 112 may be a hermetically sealed enclosure. Hermetically sealing may protect the components of the OSA 100 from oxygen, moisture, and other materials that may reduce a performance, a reliability, and/or a lifetime of the components of the OSA 100.

As indicated above, FIGS. 1A and 1B are provided as examples. Other examples may differ from what is described with regard to FIGS. 1A and 1B. The number and arrangement of devices shown in FIGS. 1A and 1B 1 are provided as an example. In practice, there may be additional devices, fewer devices, different devices, or differently arranged devices than those shown in FIGS. 1A and 1B. Furthermore, two or more devices shown in FIGS. 1A and 1B may be implemented within a single device, or a single device shown in FIG. 1 may be implemented as multiple, distributed devices. Additionally, or alternatively, a set of devices (e.g., one or more devices) shown in FIGS. 1A and 1B may perform one or more functions described as being performed by another set of devices shown in FIGS. 1A and 1B.

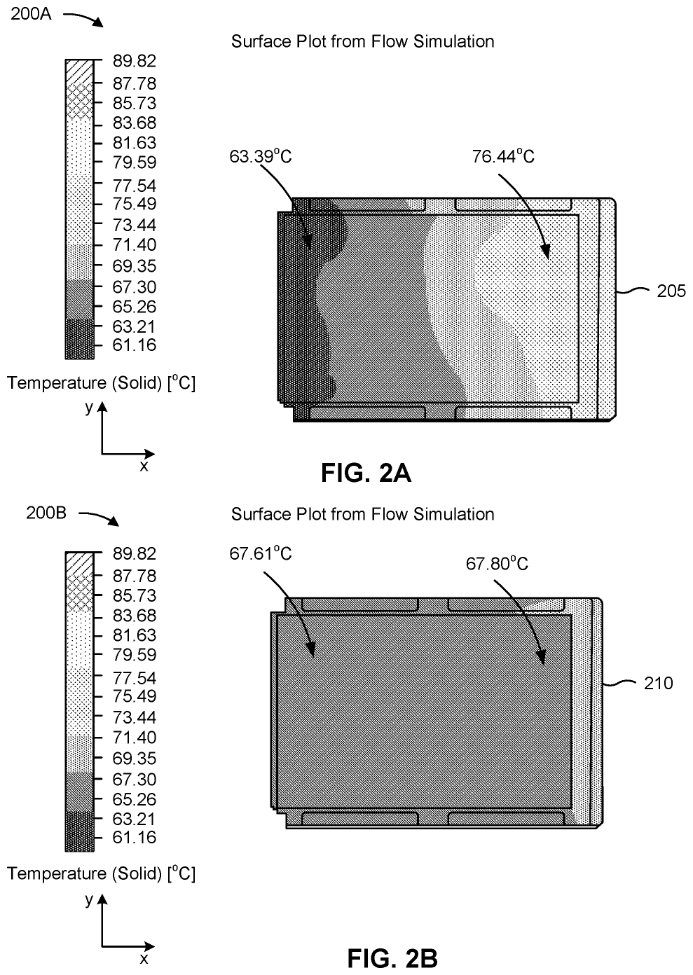

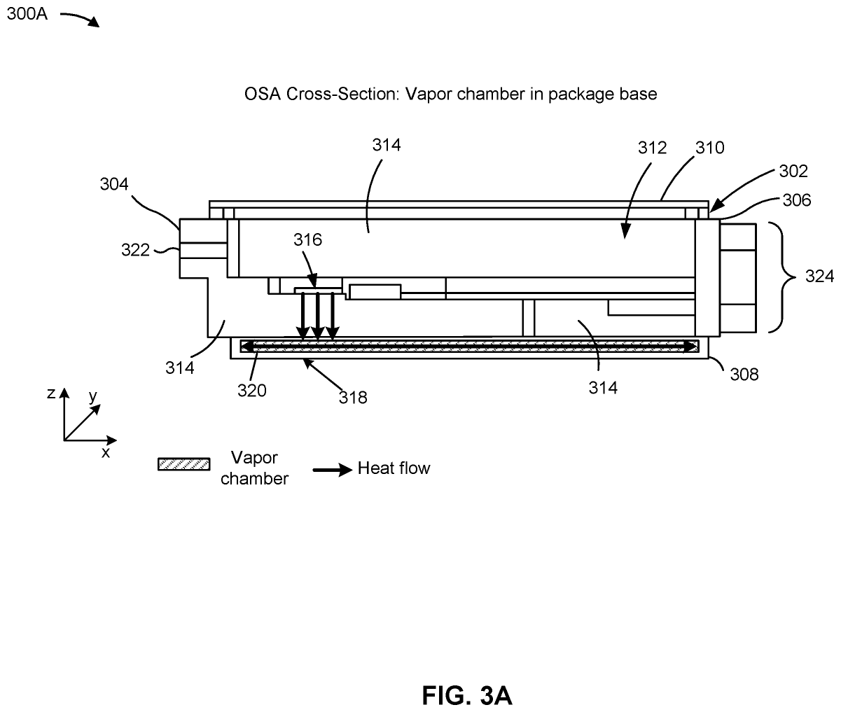

FIG. 2A is a surface plot 200A of a temperature flow simulation for an OSA 205 that does not include an integrated heat spreader. For example, the OSA 205 does not include the integrated heat spreader 120 described in connection with FIGS. 1A and 1B. According to the surface plot 200A, the OSA 205 includes a cooler region at which temperatures are at or are around 63.39° C. and a hotter region at which temperatures are at or are around 76.44° C. Thus, there is a large discrepancy in temperatures (e.g., a large temperature gradient) throughout the OSA 205 as a result of there being no integrated heat spreader.

As indicated above, FIG. 2A is provided as an example. Other examples may differ from what is described with regard to FIG. 2A.

FIG. 2B is a surface plot 200B of a temperature flow simulation for an OSA 210 that includes an integrated heat spreader, per one or more implementations of this disclosure. The OSA 210 may be similar to the OSA 100 described in connection with FIGS. 1A and 1B that includes the integrated heat spreader 120 integrated in the base 108. According to the surface plot 200B, the OSA 210 includes a cooler region at which temperatures are at or are around 67.61° C. and a hotter region at which temperatures are at or are around 67.80° C. Thus, there is only a small discrepancy in temperatures (e.g., a small temperature gradient) throughout the OSA 210 as a result of the integrated heat spreader.

As indicated above, FIG. 2B is provided as an example. Other examples may differ from what is described with regard to FIG. 2B.

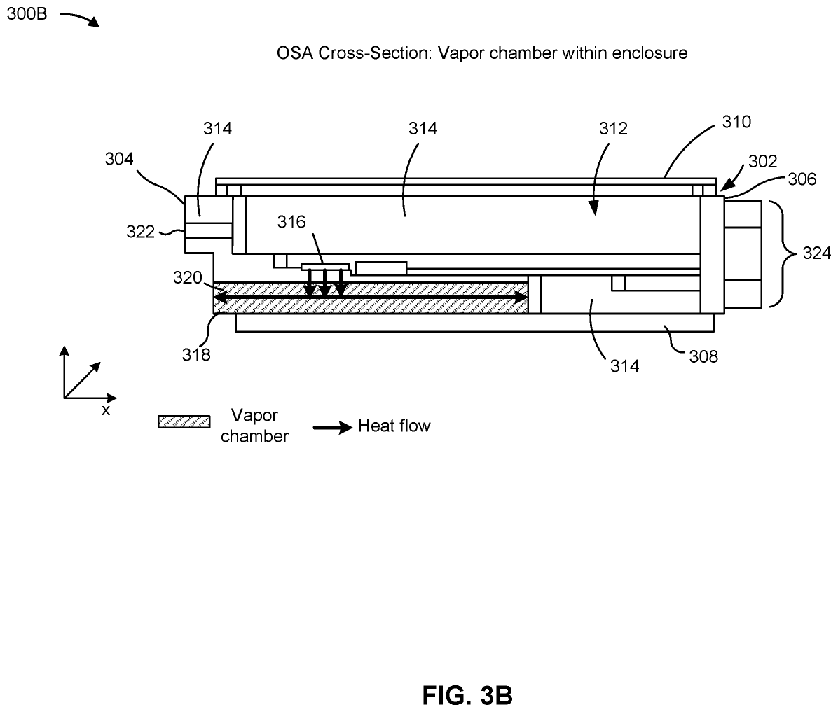

FIG. 3A is a cross-section diagram of an OSA 300A according to one or more implementations. The OSA 300A may be similar to the OSA 100 described in connection with FIGS. 1A and 1B. Accordingly, the OSA 300A may include a housing 302 that may include sidewalls 304 and 306, a base 308 (e.g., bottom package base) that extends at least partially between the sidewalls 304 and 306, and a lid 310 (e.g., a top package cover) the is arranged opposite to the base 308 and that extends between the sidewalls 304 and 306 in the first planar direction (e.g., the x-direction) and extends at least partially between the sidewalls 304 and 306. The housing 302 may be made of polymer, ceramic, metal, and/or a metal alloy. In addition, the housing 302 may define an enclosure 312 in which components of the OSA 300A are arranged, including one or more optical components (e.g., a laser source, a tunable laser, a pump laser, or a photodiode) and one or more heat-generating components (e.g., at least one laser source, at least one TEC, at least one DSP, at least one light modulator driver, at least one TIA, at least one photodiode, and/or other integrated circuit (IC) components, including one or more active components). In addition, a package assembly 314 may be arranged in the enclosure 312. The package assembly 314 may include one or more components of the OSA integrated therein. The package assembly 314 may comprise a polymer, ceramic, a metal, a metal alloy, or a combination thereof that encapsulates the one or more components of the OSA. Thus, the package assembly 314 may occupy at least part of the enclosure 312 or may occupy the entire enclosure 312.

The OSA 300A may include an IC 316 as a heat-generating component (e.g., a heat source) that produces heat during operation. Additional heat-generating components may also be provided within the enclosure 312. The base 308 may be an integrated heat spreader 318 (i.e., a phase change-based heat spreader) that includes a chamber 320 (e.g., a vapor chamber or vacuum chamber). In other words, the chamber 320 may be integrated in the base 308. The integrated heat spreader 318 may be similar to the integrated heat spreader 120 described in connection with FIGS. 1A and 1B. The base 308 may be mechanically coupled or fixed to the package assembly 314 by, for example, soldering or brazing. For example, the base 308 may be brazed to a ceramic, a metal, and/or a metal alloy of the package assembly 314. Accordingly, some of the heat produced by the IC 316 may flow to the base 308 (e.g., the heat spreader) and the base 308 may be configured to utilize phase transitions of a phase change material provided inside the chamber 320 to spread the received heat throughout the base 308. In some implementations, chamber 320 may be configured to spread the received heat evenly or substantially evenly throughout the base 308 by utilizing the phase transitions of the phase change material to equalize the heat distribution or heat flow through the chamber 320. As a result of spreading the received heat throughout the base 308, the base 308 may redistribute the heat received from one or more higher temperature regions of the OSA 300A to one or more lower temperature regions of the OSA 300A. In other words, the base 308 may redistribute heat to equalize a heat load or minimize a temperature gradient of the OSA 300A.

In some implementations, an electrical feedthrough 322 may be provided at one of the sidewalls (e.g., sidewall 304) or at the base 308 of the housing 302. The electrical feedthrough 322 may be configured to at least one of receive an electrical receive signal from an outside of the housing 302 and provide the electrical receive signal to one or more components within the enclosure 312 or transmit an electrical transmit signal from one or more components within the enclosure 312 to the outside of the housing 302. For example, the electrical feedthrough 322 may be used to receive power signals used for supplying power to more components within the enclosure 312 (e.g., to one or more of the heat-generating components). In some implementations, the electrical feedthrough 322 may be a high-speed feedthrough for transmitting or receiving high-speed data.

In some implementations, an optical port 324 may be provided at one of the sidewalls (e.g., sidewall 306) of the housing 302. The optical port 324 may be configured to receive a receive optical signal from an external source (e.g., from an optical transmitter) and/or transmit a transmit optical signal to an external receiver (e.g., to an optical receiver). Thus, the OSA 300A may include circuitry and optical components associated with receiving and/or transmitting optical signals. In some implementations, the optical signals may be optical communication signals and the optical port 324 may be coupled to an optical fiber used for transmitting the optical communication signals between the optical transmitter and the optical receiver.

As indicated above, FIG. 3A is provided as an example. Other examples may differ from what is described with regard to FIG. 3A. For example, in some implementations, the integrated heat spreader 318 may be integrated in the lid 310 instead of the base 308. The lid 310 may be mechanically coupled or fixed to the package assembly 314 by, for example, soldering or brazing.

FIG. 3B is a cross-section diagram of an OSA 300B according to one or more implementations. The OSA 300A may be similar to the OSA 300A described in connection with FIG. 3A, with the exception that the integrated heat spreader 318 (i.e., a phase change-based heat spreader) may be arranged within (e.g., integrated within) the enclosure 312 of the OSA 300A instead of integrated in the base 308. In some implementations, the integrated heat spreader 318 may be mechanically coupled to the base 308, for example, by soldering or brazing. The integrated heat spreader 318 may extend partially along the base 308 or may extend fully along the base 308 to spread heat throughout the OSA 300B and to equalize a heat load or minimize a temperature gradient of the OSA 300B.

As indicated above, FIG. 3B is provided as an example. Other examples may differ from what is described with regard to FIG. 3B. For example, in some implementations, the integrated heat spreader 318 may be mechanically coupled to the lid 310, for example, by soldering or brazing, instead of to the base 308.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical sub-assembly, comprising:
a housing that defines an enclosure, wherein the housing comprises sidewalls and a base that extends between the sidewalls, and wherein one of the sidewalls comprises an optical port configured to at least one of receive a receive optical signal or transmit a transmit optical signal;
at least one component integrated within the enclosure, wherein the at least one component is configured to generate heat during operation; and
an integrated heat spreader that extends at least partially between the sidewalls, wherein the integrated heat spreader is integrated in the base or integrated within the enclosure, wherein the integrated heat spreader is thermally coupled to the at least one component to receive heat from the at least one component, wherein the integrated heat spreader contains a phase change material that is configured to undergo phase transitions between a first phase state and a second phase state, and wherein the integrated heat spreader is configured to utilize the phase transitions to spread heat throughout the integrated heat spreader,
wherein the integrated heat spreader is configured to equalize a heat load or minimize a temperature gradient of the optical sub-assembly.

2. The optical sub-assembly of claim 1, wherein the integrated heat spreader forms the base, and
wherein the integrated heat spreader is mechanically coupled to at least one sidewall of the sidewalls.

3. The optical sub-assembly of claim 2, wherein the integrated heat spreader comprises a chamber that contains the phase change material, and
wherein the chamber extends substantially throughout the base.

4. The optical sub-assembly of claim 1, further comprising a package assembly disposed within the enclosure, and
wherein the integrated heat spreader is mechanically coupled to the package assembly.

5. The optical sub-assembly of claim 1, wherein the housing is made of at least one of a polymer, a ceramic, a metal, or a metal alloy.

6. The optical sub-assembly of claim 1, further comprising:
an electrical feedthrough arranged at the base or at a sidewall, wherein the electrical feedthrough is configured to at least one of receive a first electrical signal from an outside of the housing and provide the first electrical signal within the enclosure or transmit a second electrical signal from the enclosure to the outside of the housing.

7. The optical sub-assembly of claim 1, further comprising:
an optical component arranged within the enclosure, wherein the optical component is a laser source, a tunable laser, a pump laser, or a photodiode.

8. The optical sub-assembly of claim 1, wherein each component of the at least one component is an active component.

9. The optical sub-assembly of claim 1, wherein the at least one component includes at least one of a laser source, a thermoelectric cooler (TEC), a digital signal processor (DSP), a light modulator driver, a transimpedance amplifier (TIA), or an integrated circuit.

10. The optical sub-assembly of claim 1, wherein the housing comprises a lid that extends between the sidewalls, arranged opposite to the base.

11. The optical sub-assembly of claim 10, wherein the enclosure is a hermetically sealed enclosure.

12. An optical sub-assembly, comprising:
a housing;
at least one component integrated within the housing, wherein the at least one component is configured to generate heat during operation; and
an integrated heat spreader integrated as part of the housing or integrated within the housing, wherein the integrated heat spreader is thermally coupled to the at least one component to receive heat from the at least one component, wherein the integrated heat spreader contains a phase change material that is configured to undergo phase transitions between a first phase state and a second phase state, and wherein the integrated heat spreader is configured to utilize the phase transitions to spread heat throughout the integrated heat spreader,
wherein the integrated heat spreader is configured to equalize a heat load or minimize a temperature gradient of the optical sub-assembly.

13. The optical sub-assembly of claim 12, wherein the housing comprises a base, and
wherein the integrated heat spreader is integrated in the base.

14. The optical sub-assembly of claim 13, wherein the integrated heat spreader forms the base.

15. The optical sub-assembly of claim 13, wherein the integrated heat spreader comprises a chamber that contains the phase change material, and
wherein the chamber extends substantially throughout the base.

16. The optical sub-assembly of claim 13, further comprising a package assembly disposed within the housing and encapsulates the at least one component, and
wherein the base is brazed or soldered to the package assembly.

17. The optical sub-assembly of claim 12, wherein the housing is a hermetically sealed housing.

18. The optical sub-assembly of claim 12, wherein the housing comprises a base, sidewalls, and a lid arranged opposite to the base,
wherein the housing forms an enclosure, and
wherein the integrated heat spreader integrated within the enclosure and is mechanically coupled to the base or to the lid.

19. The optical sub-assembly of claim 12, wherein the housing comprises a base, sidewalls, and a lid arranged opposite to the base,
wherein the integrated heat spreader is integrated in the lid.

20. The optical sub-assembly of claim 19, wherein the integrated heat spreader forms the lid.

21. The optical sub-assembly of claim 12, wherein the housing comprises a base, sidewalls, and a lid arranged opposite to the base, and
wherein the integrated heat spreader is integrated in at least one of the sidewalls.
